(19) United States
(12) Patent Application Publication
(10) Pub. No.: US 2004/0195669 A1
(43) Pub. Date: Oct. 7, 2004

(54) Integrated circuit packaging apparatus and method

(76) Inventors: Wendy Lee Wilkins, Eau Claire, WI (US); Kevin Wade Hampton, Eau Claire, WI (US); Jeffrey Thomas Barr, Bloomer, WI (US)

Correspondence Address: Paul E. Franz, Jones Day, North Point, 901 Lakeside Avenue, Cleveland, OH, 44114, US

(21) Appl. No.: 10/729,734

(22) Filed: Dec. 5, 2003

Related U.S. Application Data
(60) Provisional application No. 60/461,020, filed on Apr. 7, 2003.

(51) Int. Cl. H01L 21/44; H01L 23/053

(52) U.S. Cl. 257/698; 257/700; 257/737; 438/613

(57) ABSTRACT

An integrated circuit apparatus for facilitating the interconnection of one or more circuitry manufacture includes a carrier substrate defining a top surface and a bottom surface. Carrier substrate vias penetrate from the top surface to the bottom surface of the carrier substrate and define interior via surfaces. Carrier substrate cavities are formed on the top and/or bottom surfaces of the carrier substrate and define interior cavity surfaces. The carrier substrate is configured to receive one or more circuitry manufacture on the top and bottom surfaces, the interior via surfaces, and the interior cavity surfaces.

This Application claims the benefit of and priority to U.S. Patent Application Ser. No. 60/461,020, filed on Apr. 7, 2003, the entire disclosure of which is incorporated herein by reference.

### BACKGROUND AND SUMMARY

This patent document generally relates to the packaging of Integrated Circuits (ICs), passive components, and Micro Electro Mechanical Systems (MEMS), and in particular relates to a three-dimensional packaging system that can be used to electrically interconnect various types of microelectronic devices.

There are multiple existing methods for packaging ICs and MEMS devices with other electronic components. Multiple component packages can be used to package a variety of components and chips together, and single component packages can be used to assemble single components onto a printed circuit board or connector. These single-chip and multi-chip packages can be fabricated out of a variety of materials such as ceramic, laminate material, plastic, or silicon. The package can be constructed on top of the chip (“chips first”) or the chip can be attached to the package (“chips last”). An interconnect layer comprising a silicon substrate layer having conductive vias may have one or more ICs or MEMS attached to one or both sides of the silicon substrate layer.

Depending on the application of the device that is to be constructed by a multiple component package, it may be desirable to package ICs and MEMS components on one side of a substrate, on both sides of the substrate, within the substrate, or over a cavity in the substrate. For example, if an accelerometer is to be constructed, one possible design is to mount a MEMS accelerometer over a cavity in the substrate, and mount an IC operable to communicate with the MEMS accelerometer on the other side of the substrate.

An integrated circuit apparatus for facilitating the interconnection of one or more circuitry manufacture comprises a carrier substrate, one or more carrier substrate vias, and one or more carrier substrate cavities. The carrier substrate defines a top surface and a bottom surface and is configured to receive one or more circuitry manufacture on the top surface and the bottom surface. The one or more carrier substrate vias penetrate the carrier substrate so that the carrier substrate vias define vias from the top surface to the bottom surface of the carrier substrate and further define interior via surfaces. The carrier substrate vias are configured to receive one or more circuitry manufacture on the interior via surfaces. The one or more carrier substrate cavities are formed on the top and/or bottom surfaces of the carrier substrate and define interior cavity surfaces and are configured to receive one or more circuitry manufacture on the interior cavity surfaces.

A method for facilitating the interconnection of one or more circuitry manufacture comprises providing a carrier substrate defining a top surface and a bottom surface; creating one or more carrier substrate vias penetrating the carrier substrate so that the carrier substrate vias define vias from the top surface to the bottom surface of the carrier substrate and further define interior via surfaces; and creating one or more carrier substrate cavities on the top and/or bottom surfaces of the carrier substrate so that the one or more carrier substrate cavities define interior cavity surfaces. The top and bottom surfaces of the carrier substrate, the interior via surfaces, and the interior cavity surfaces are configured to receive one or more circuitry manufacture.

An integrated circuit apparatus for facilitating the interconnection of one or more circuitry manufacture comprises means for defining a top carrier substrate surface and a bottom carrier substrate surface and for receiving one or more circuitry manufacture on the top carrier substrate surface and the bottom carrier substrate surface; means for defining vias from the top carrier substrate surface to the bottom carrier substrate surface and for defining interior via surfaces for receiving one or more circuitry manufacture; and means for defining cavity surfaces on the top and/or bottom carrier substrate surfaces and for receiving one or more circuitry manufacture on the interior cavity surfaces.

### BRIEF DESCRIPTION OF THE DRAWINGS

FIG. 1 is a cross section view of an illustrative carrier substrate;

FIG. 2 is a cross section view of the carrier substrate having a deposited dielectric;

FIG. 3 is a cross section view of the carrier substrate having a conductive layer in the vias in the carrier substrate;

FIG. 4 is a cross section view of the carrier substrate having a thin film interconnect;

FIG. 5 is a cross section view of the carrier substrate having attached circuitry above the cavities;

FIG. 6 is a cross section view of the carrier substrate having circuitry attached inside the cavities; and

FIG. 7 is a cross section view of the carrier substrate having cavities on both sides of the carrier.

### DETAILED DESCRIPTION

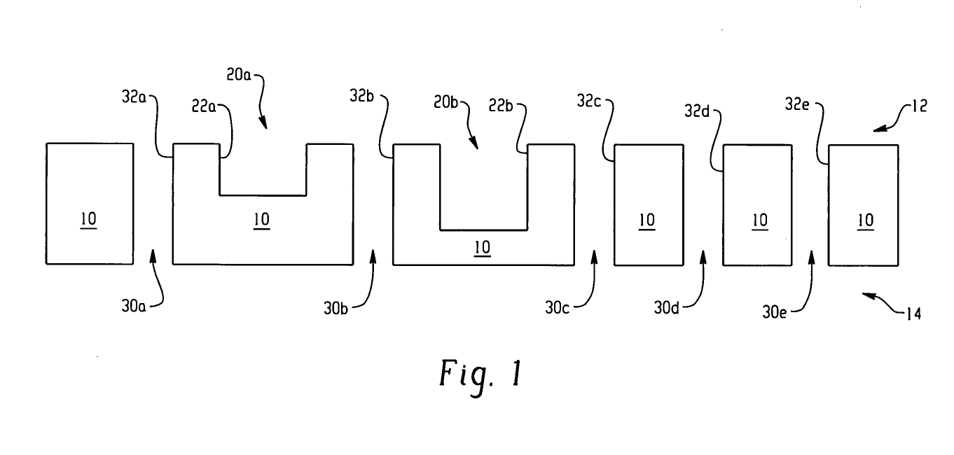

FIG. 1 is a cross section view of an illustrative carrier substrate 10 defining a top surface 12 and a bottom surface 14. The carrier substrate 10 may be fabricated on a single silicon wafer. The wafer thickness is typically dictated by the application. A plurality of cavities 20a and 20b may be formed at different depths using a deep reactive ion etch (DRIE) process. The cavities 20a and 20b defined interior cavity surfaces 22a and 22b. Alternatively, the cavities 20a and 20b may be formed using conventional anisotropic silicon wet etch processes. Other methods or processes for forming the cavities may also be used.

A plurality of conductive vias 30a-30e may be created proximate to the cavities 20a and 20b. The conductive vias 30a-30e penetrate the carrier substrate 10 so that the conductive vias 30a-30e form vias from the top surface 12 to the bottom surface 14 of the carrier substrate 10, and define inner peripheries 32a-32e. The conductive vias 30a-30e are typically not conductive without a conductive coating or core, as the conductive vias 30a-30e define the inner peripheries of the 32a-32e which are, in turn, surfaces of the carrier substrate 10. Thus, the conductive vias 30a-30e have the same conductivity characteristic of the carrier substrate 10. However, the conductive vias 30 may be later coated with a conductive material to form a conductive path from the top surface 12 to the bottom surface 14 of the carrier substrate 10. The conductive vias 30a-30e may be created using industry standard laser or DRIE processes. Other methods of creating the vias 30a-30e may also be used.

The carrier substrate 10 is configured to receive circuitry manufacture on both the top surface 12 and the bottom surface 14. The circuitry manufacture may include dielectric coatings, conductive materials, insulating materials, passive circuit components, active circuit components, ICs, MEMS, bonding materials, or other circuitry-related articles of manufacture. Similarly, the interior cavity surface 22a and 22b of the cavities 20a and 20b and the inner peripheries 32a-32e of the conductive vias 32a-32e are also configured to receive one or more circuitry manufacture. For example, a first circuitry manufacture, such as an IC, may be mounted on the carrier substrate 10 by one or more additional circuitry manufacture, such as an adhesive or solder bonding.

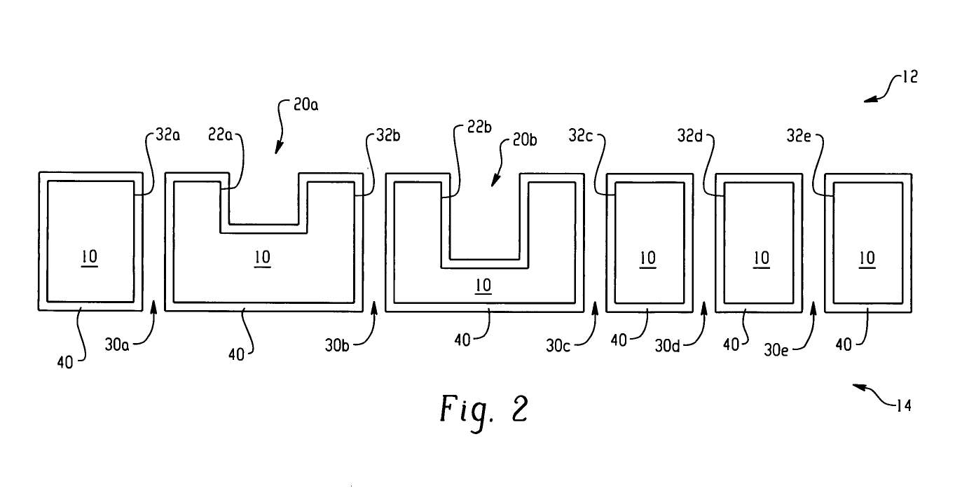

Depending on the particular substrate used to realize the carrier substrate 10, a dielectric circuitry manufacture may be deposited on the carrier substrate 10 after the cavities 20 and conductive vias 30 are created. FIG. 2 is a cross section view of the carrier substrate 10 having a deposited dielectric 40. The inner peripheries 32a-32e of the vias 30a-30e may be isolated by use of plasma enhanced chemical vapor deposition (PECVD) deposited dielectric 40 such as SiO₂ or by thermal oxidation. Additionally, as shown in FIG. 2, the top surface 12, the bottom surface 14, and the interior cavity surfaces 22a and 22b of the carrier substrate 10 may likewise be isolated by the deposited dielectric 40.

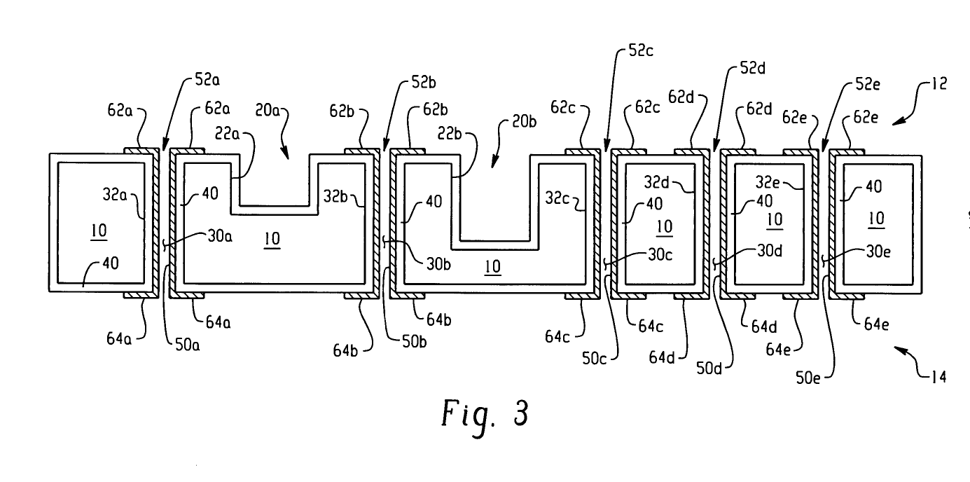

FIG. 3 is a cross section view of the carrier substrate 10 having conductive layers 50a-50e deposited within the vias 30a-30e. The conductive layers 50a-50e in the visa 30a-30e are typically deposited after the dielectric 40 is applied. The conductive layers 50a-50e may be created by physical vapor deposition (PVD) sputtering techniques, CVD metallization, or by plating. In one embodiment, combination of sputtering followed by electroplating may be used to improve metal coverage and reduce the resistance.

The vias 30a-30e are typically not completely filled with conductive material that comprises the conductive layers 50a-50e, as indicated by the spaces 52a-52e defined by the conductive layers 50a-50e deposited along the inner periphery defined by the inner peripheries 32a-32e and the dielectric 40. By depositing the conductive layers 50a-50e only along the inner periphery defined by the inner peripheries 32a-32e and the dielectric 40, thermal stresses caused by the coefficient of thermal expansion (CTE) mismatch between the conductive material and the substrate material are minimized. In another embodiment, however, the conductive vias 30a-30e may be completely filled with the conductive material.

Illustrative conductive materials that may comprise the conductive layers 50a-50e include silver, copper, aluminum, gold, platinum, and other conductive metals. Alternatively, conductive polymers or other conductive materials may also be used.

Conductive layers 62a-62e and 64a-64e are deposited on the top surface 12 to the bottom surface 14 of the carrier substrate 10 to form interconnections from the top surface 12 to the bottom surface 14, respectively. The conductive layers 62a-62e and 64a-64e are deposited around the circumference of the openings of the vias 30a-30e and may be patterned using standard photolithography techniques common to the printed circuit board industry. Either an etch back or a patterned plating process may be used. The combination of cavities 20a and 20b and conductive vias 30a-30e facilitates denser packaging of circuitry manufacture.

While the conductive layers 62a-62e and 64a-64e are illustrated as extending around the entire circumference of the openings of the conductive vias 30a-30e, the conductive layers 62a-62e and 64a-64e may alternatively be patterned to extend only around a portion of the entire circumference of the openings of the conductive vias 30a-30e. For example, the conductive layer 62a may be patterned to omit the portion of the conductive layer 62a extending toward the cavity 20a.

Silicon is typically used as the base substrate. Selecting the base substrate from silicon thermally matches the carrier substrate 10 to the CTE of typical ICs. Furthermore, the thermal conductivity of silicon also facilitates efficient removal of heat from the ICs and also facilitates the package to be built using standard semiconductor processes. Multiple parts can be fabricated at once, which reduces the cost of production. Finally, while a base substrate of silicon has been illustrated, other substrate materials may also be used. These other materials may include Invar, quartz, ceramic, or even graphite, for example, depending on tolerance requirements. For some of these other materials fewer circuitry manufacture may be needed. For example, if the base substrate is ceramic, then a dielectric coating may be omitted, depending on the particular ceramic used.

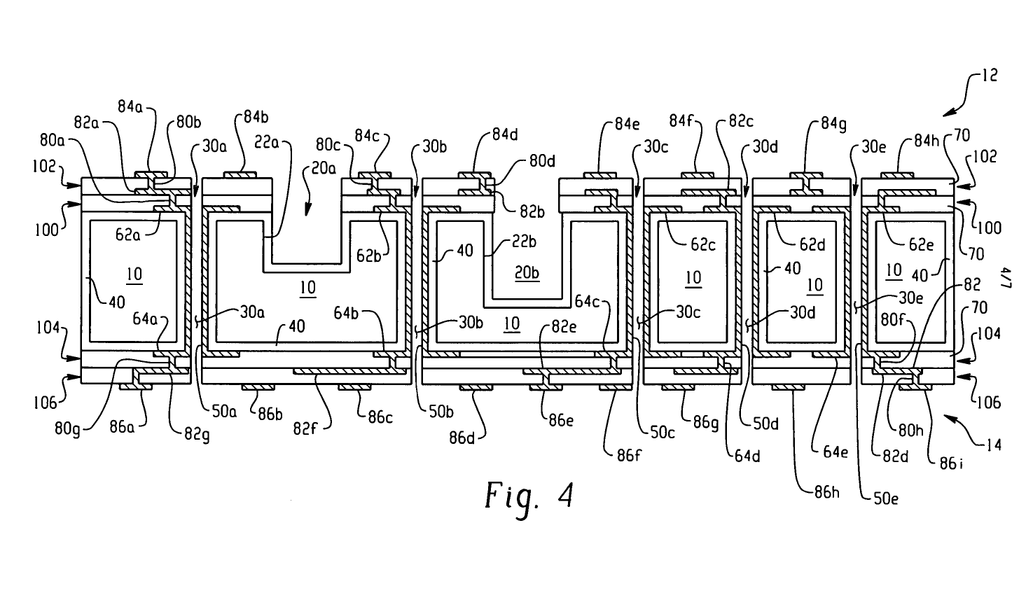

FIG. 4 is a cross section view of the carrier substrate 10 having a thin film interconnect. Layers of thin film interconnect 100, 102, 104 and 106 may be added to either one or both of the top surface 12 and the bottom surface 14, as shown in FIG. 4. One process to apply the additional layers is to coat the carrier substrate 10 with a dielectric 70 such as polyimide, or bisbenzocyclobutene (BCB), or other suitable dielectric. Spray, dip, extrusion or even spin coating application processes may be used to deposit the dielectric 70.

While four layers of thin film interconnect 100, 102, 104 and 106 are shown in FIG. 4, additional layers may be created, or even fewer layers may be created, depending on the interconnection requirements for the end application of the carrier substrate 10. Each layer may be of the same dielectric material, or may comprise different dielectrics, depending on the application requirements.

For the example carrier substrate 10 of FIG. 4, the cavities 20a and 20b are left open. Interconnecting vias 80a-80g may be made through the dielectric layers of the thin film interconnect 100, 102, 104 and 106 to electrically connect bonding pads 82a-82g in each layer of the thin film interconnect 100, 102, 104 and 106. To avoid congestion in the drawings, not all interconnecting vias 80 and bonding pads 82 are individually referenced.

Another layer of conductive interconnect may be added to the exposed surfaces of the thin film interconnect layers 102 and 106 to form bonding pads 84a-84h and 86a-86g. The layer may be added, for example, by PVD sputtering followed by photo patterning and plating or blanket metallization and etch back. Metals such as aluminum, copper, or gold may be used as the conductive layers within the thin film interconnect 100. Other conductive metals or materials may also be used, however. Additional layers of thin film interconnect may be added in a similar fashion, depending on the complexity of the circuitry to be attached or affixed to the carrier substrate 10.

Components on the top surface 12 and bottom surface 14 of the carrier substrate 10 may thus be interconnected via multiple layers of thin film interconnect 100, 102, 104 and 106 and the conductive vias 30. Other components can be attached to the bonding pads 84a-84h and 86a-86g on the top surfaces of the thin film interconnect 102 and 106. The carrier substrate 10 may be connected or attached to other carrier substrates, printed circuit boards, or other second level packages through the use of gold bumps, solder bumps, or conductive adhesives. Furthermore, because of the conductive vias 30a-30e through the carrier substrate 10, the carrier substrate 10 and attached circuitry may further be stacked on top of other carrier substrates 10 or other circuitry, reducing the x-y footprint of the package and reducing signal latency.

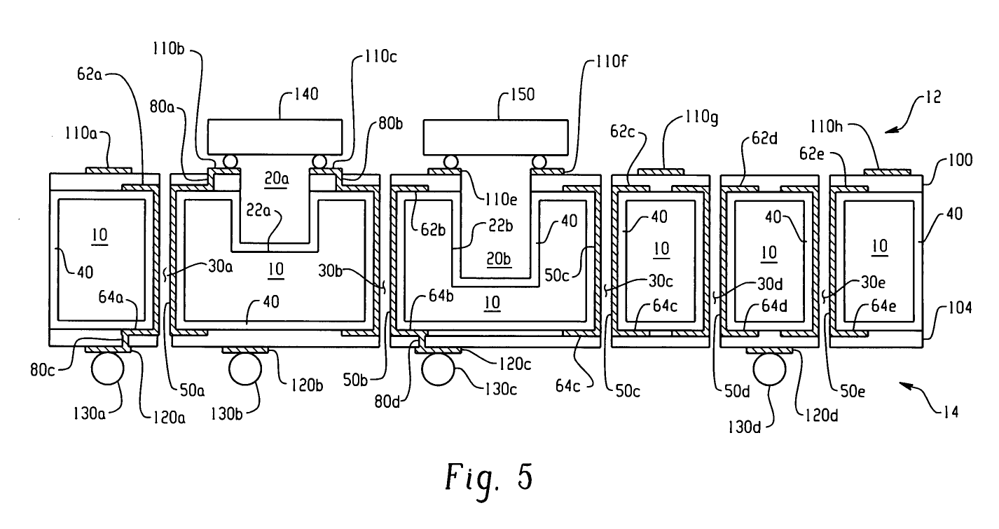

FIG. 5 is a cross section view of the carrier substrate 10 having attached circuitry 140 and 150 above the cavities 20a and 20b. The final layer of conductive material on the top and bottom surfaces 12 and 14 of this carrier substrate 10 package is typically pad layers comprising bonding pads 110a-110h and 120a-120d. The bonding pads 110a-110h and 120a-120d are fabricated using an appropriate metallurgy or conductive material to make the next level of interconnection. For example, if the ICs or MEMS devices are solder attached to the carrier substrate 10, the pad layer of bonding pads 110a-110h on the top surface 12 of the carrier substrate 10 may have the under bump metallurgy required for a solder attach. The bonding pads 120a-120d on the bottom surface 14 of the carrier substrate 10 may have a different metallurgy or conductive material to allow for a different type of attachment or bonding to other devices, e.g. gold bumps or copper bumps 130a-130d.

The bonding pads 11Oa-110h and 120a-120d on the top and bottom surfaces 12 and 14 of the carrier substrate 10 may be isolated from the underlying thin film circuitry 100 and 104 by an organic dielectric layer such as polyimide or BCB. The bonding pads 110a-110h and 120a-120d may then be connected to the conductive layers 62a-62e and 64a-64e through conductive vias 80a-80f in the thin film interconnect 100 and 104.

In one embodiment, the carrier substrate 10 may facilitate the packaging of MEMS devices and associated ICs operable to communicate with the MEMS devices. As shown in FIG. 5, for example, a MEMS device 140 may be mounted over the cavity opening 20a and an ASIC 150 to control the MEMS device 140 is flip chip attached proximate to the MEMS device 140 on the top surface 12 of the carrier substrate 10 package. While the ASIC 150 is shown as being mounted over the cavity 20b, the ASIC 150 may instead be mounted over one or more of the vias 30a-30e.

In another embodiment, the ASIC 150 may be mounted on the bottom surface 14 of the carrier substrate 10. In still another embodiment, the ASIC 150 may be mounted directly on the carrier substrate 10 to conductive layers 62 or 64, or to other bonding pads on the carrier substrate 10. The MEMS device 140 is in electrical communication with bonding pads 120a and 120c through conductive vias 80a-8d, which electrically connect bonding pads 110b and 110c to bonding pads 120a and 120c through the conductive vias 30a and 30b. An appropriate metallurgy for the bonding pads 120a and 120c would be implemented to facilitate connection of the ASIC 150 to the bonding pads 120a and 120c.

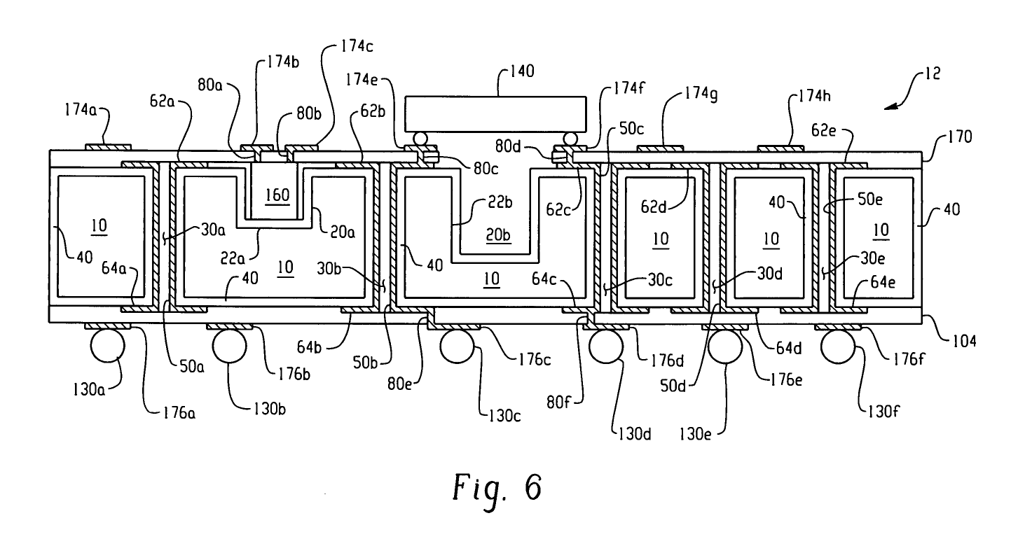

FIG. 6 is a cross section view of the carrier substrate 10 having circuitry attached inside the cavities 20. In this embodiment, the top surface 12 of the package 10 may include the cavities 20a and 20b, a layer of thin film interconnect 170, and a pad layer comprising bonding pads 174a-174h for solder connection of the MEMS device 140 to the carrier substrate 10. The bottom surface 14 of the silicon carrier substrate 10 also includes a layer of thin film interconnect 172 and a pad layer comprising bonding pads 176a-176f for attachment to another assembly through metallurgy bumps 130a-130f.

The conductive vias 30b and 30c electrically connect circuitry on the top surface 12, such as the MEMS device 150, to the bonding pads 176c and 176d on the bottom surface 14 of the carrier substrate 10. The upper and lower surfaces 10 and 12 of both sides of the carrier substrate 10 and the inner surfaces 32a-32e of the vias 30a-30e are isolated from the first layer of thin film interconnect by a layer of silicon oxide 40.

After the cavities 20a and 20b and vias 30a-30e are created and the vias 30a-30e are isolated and metallized, ICs and components, such as a capacitor 160, may be placed in the cavities, as shown in FIG. 6. A dielectric film 170 may be placed over the cavities 20a and 20b and vias 30a-30e for single or multiple layers of thin film interconnect fabrication on both the upper and lower surfaces 12 and 14 of the carrier substrate 10. The capacitor 160 is a two-terminal capacitor having the terminals connected to bonding pads 174b and 174c through vias 80a and 80b. Electrical connections are made from the upper surface 12 to the lower surface 14 by means of the conductive vias 30a-30e and vias 80a-80f in the thin film interconnect.

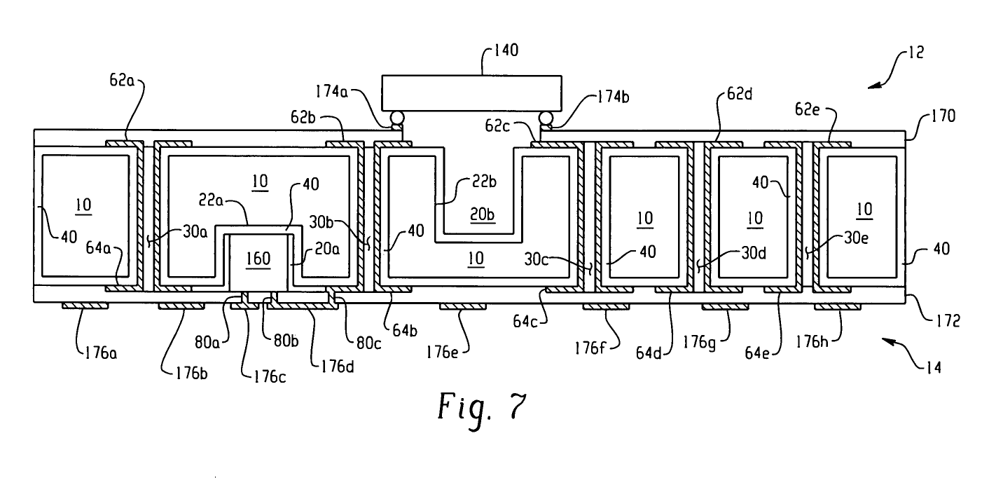

Cavities 20a and 20b may be distributed on both sides of the carrier substrate 10, as shown in FIG. 7. ICs, MEMS devices, or other components may be mounted inside or over the cavities 20a and 20b on both the top and bottom surfaces 12 and 14 of the carrier substrate 10. In another embodiment, a passive device associated with a MEMS device 140 or IC 150 may be placed in a cavity, such as cavity 20b, above which the MEMS device 140 or IC 150 is to be mounted. Additional MEMS device 140 or IC 150 may be mounted directly on the carrier substrate 10 to conductive layers 62 or 64, or to other bonding pads on the carrier substrate 10. Accordingly, the overall footprint of the resulting circuitry is reduced.

In summary, a variety of cavity 20 and conducting via 30 configurations may be implemented in a carrier substrate 10. The vias 30 may be sealed at the top and bottom with layers of dielectric film. Additional layers of thin film interconnect may be added to the upper and lower surfaces 12 and 14 of the carrier substrate 10. The ICs may be mounted within the cavities 20 or attached to the thin film interconnect to either the upper and lower surfaces 12 and 14. MEMS devices may be mounted over the cavities 20, or, if the MEMS devices may operate properly in a cavity 20, the MEMS device may be mounted in the cavities 20. Passive devices, such as resistors and capacitors, may also be mounted in the cavities 20, and additional circuitry may further be mounted over the cavities 20 in which the passive devices are mounted.

Additionally, while the cavities 20 and the vias 30 have been illustrated in proximate disposition, vias 30 may also be formed on the bottom surface of one or more cavities 20. For example, a cavity 20 may be formed on the top surface 12 of the carrier substrate 10, and vias 30 may be formed to penetrate from the bottom surface of the cavity 20 to the bottom surface 14 of the carrier substrate 10. Conductive materials may then be deposited on the interior via surfaces 32 so that devices mounted in the cavity 20 on the top surface 12 of the carrier substrate 10 may be in electrical communication with circuitry manufacture deposited on or attached to the bottom surface 14 of the carrier substrate 10. Cavity vias 30 may be formed in the cavity 20 after the cavity 20 has been formed. Alternatively, the cavity vias 30 may first be formed, and then the cavity 20 may be formed in the area in which the cavity vias 30 are formed.

The devices and methods disclosed herein provide for flexibility in packaging a variety of components that are of different size and thickness, and also allows for combining MEMS devices with ICs and passive components. The carrier substrate may be fabricated with pads for wire bonding, adhesive attach, solder bumps, or gold bumps on both the top and bottom which allows electrical devices to be interconnected in a variety of ways with other assemblies such as connectors, modules, and printed circuit boards. Thus, the packaging of multiple types of electronic components such as ICs, MEMS, capacitors, and other electronic modules together in one package may be facilitated by the devices and methods disclosed herein.

The embodiments described herein are examples of structures, systems or methods having elements corresponding to the elements of the invention recited in the claims. This written description may enable those of ordinary skill in the art to make and use embodiments having alternative elements that likewise correspond to the elements of the invention received in the claims. The intended scope of the invention thus includes other structures, systems or methods that do not differ from the literal language of the claims, and further includes other structures, systems or methods with insubstantial differences from the literal language of the claims.

What is claimed is:

1. An integrated circuit apparatus for facilitating the interconnection of one or more circuitry manufacture, comprising:
a carrier substrate defining a top surface and a bottom surface, the carrier substrate configured to receive one or more circuitry manufacture on the top surface and the bottom surface;
one or more carrier substrate vias penetrating the carrier substrate so that the carrier substrate vias define vias from the top surface to the bottom surface of the carrier substrate and further define interior via surfaces, the one or more carrier substrate vias configured to receive one or more circuitry manufacture on the interior via surfaces; and
one or more carrier substrate cavities, the one or more carrier substrate cavities formed on the top and/or bottom surfaces of the carrier substrate, the one or more carrier substrate cavities defining interior cavity surfaces and configured to receive one or more circuitry manufacture on the interior cavity surfaces.

2. The integrated circuit apparatus of claim 1, further comprising an electrically conductive material deposited on the interior via surface of one or more carrier substrate vias to form an electrical conductive path from the top surface of the carrier substrate to the bottom surface of the carrier substrate.

3. The integrated circuit apparatus of claim 2, further comprising a first thin film interconnect formed on the top surface of the carrier substrate and a second thin film interconnect formed on the bottom surface of the carrier substrate, the first and second thin film interconnect defining a first pad layer and a second pad layer and further comprising one or more conductive paths from the first and second pad layers to the electrically conductive material deposited on the interior via surfaces.

4. The integrated circuit apparatus of claim 2, further comprising first circuitry mounted to the carrier substrate by one or more circuitry manufacture and atop a carrier substrate cavity.

5. The integrated circuit apparatus of claim 4, wherein the first circuitry comprises a Micro Electro Mechanical System (MEMS) device.

6. The integrated circuit apparatus of claim 5, further comprising second circuitry mounted to the carrier substrate by one or more circuitry manufacture and proximate to one or more substrate vias.

7. The integrated circuit apparatus of claim 6, wherein the second circuitry comprises an integrated circuit operable to communicate data to and from the MEMS device, and wherein the integrated circuit is in electrical communication with the MEMS device through one or more conductive paths deposited on the interior surfaces of the substrate vias.

8. The integrated circuit apparatus of claim 2, further comprising first circuitry mounted to the carrier substrate by one or more circuitry manufacture and within a carrier substrate cavity.

9. The integrated circuit apparatus of claim 8, further comprising second circuitry mounted to the carrier substrate by one or more circuitry manufacture and atop the carrier substrate cavity.

10. The integrated circuit apparatus of claim 9, wherein the first circuitry comprises a passive circuit device and the second circuitry comprises a Micro Electro Mechanical System (MEMS) device, and wherein the MEMS device is in electrical communication with the passive circuit device.

11. The integrated circuit apparatus of claim 3, wherein the first pad layer defines a first metallurgy and the second pad layer defines a second metallurgy.

12. The integrated circuit apparatus of claim 11, wherein the first metallurgy is a wire bonding pad metallurgy and the second metallurgy is a Ball Grid Array (BGA) metallurgy.

13. The integrated circuit apparatus of claim 1, wherein the one or more carrier substrate vias are in proximate disposition to the carrier substrate cavities.

14. The integrated circuit apparatus of claim 1, further comprising one or more carrier substrate cavity vias penetrating the carrier substrate so that the carrier substrate cavity vias define vias from a bottom surface of one or more carrier substrate cavities to the bottom surface of the carrier substrate and further define interior via surfaces, the one or more carrier substrate cavity vias configured to receive one or more circuitry manufacture on the interior via surfaces.

15. The integrated circuit apparatus of claim 1, wherein the carrier substrate is silicon.

16. The integrated circuit apparatus of claim 1, wherein the one or more circuitry manufacture comprises a conductive material.

17. A method for facilitating the interconnection of one or more circuitry manufacture, comprising:
providing a carrier substrate defining a top surface and a bottom surface,
creating one or more carrier substrate vias penetrating the carrier substrate so that the carrier substrate vias define vias from the top surface to the bottom surface of the carrier substrate and further define interior via surfaces; and
creating one or more carrier substrate cavities on the top and/or bottom surfaces of the carrier substrate so that the one or more carrier substrate cavities define interior cavity surfaces;
wherein the top and bottom surfaces of the carrier substrate, the interior via surfaces, and the interior cavity surfaces are configured to receive one or more circuitry manufacture.

18. The method of claim 17, further comprising depositing an electrically conductive material on the interior via surface of one or more carrier substrate vias to form an electrical conductive path from the top surface of the carrier substrate to the bottom surface of the carrier substrate.

19. The method of claim 18, further comprising:
forming a first thin film interconnect on the top surface of the carrier substrate;
forming a second thin film interconnect on the bottom surface of the carrier substrate;
forming a first pad layer on the first thin film interconnect;
forming a second pad layer on the second thin film interconnect; and
forming one or more conductive paths from the first and second pad layers to the electrically conductive material deposited on the interior via surfaces.

20. The method of claim 19, wherein forming a first pad layer on the first thin film interconnect comprises forming a first pad layer of a first metallurgy and forming a second pad layer on the second thin film interconnect comprises forming a second pad layer of a second metallurgy.

21. The method of claim 18, further comprising:
attaching by one or more circuitry manufacture a first circuitry to the carrier substrate atop a carrier substrate cavity and proximate to one or more carrier substrate vias;
attaching by one or more circuitry manufacture a second circuitry to the carrier substrate and proximate to one or more carrier substrate vias; and
electrically connecting the first circuitry to the second circuitry through the electrical conductive paths on the one or more interior via surfaces.

22. The method of claim 21, wherein the first circuitry comprises a Micro Electro Mechanical System (MEMS) device and the second circuitry comprises an integrated circuit operable to communicate data to and from the MEMS device.

23. The method of claim 17, further comprising creating one or more carrier substrate cavity vias penetrating the carrier substrate so that the carrier substrate cavity vias define vias from a bottom surface of a carrier substrate cavity to the bottom surface of the carrier substrate and further define interior via surfaces configured to receive one or more circuitry manufacture.

24. The method of claim 17, wherein the one or more circuitry manufacture comprises a conductive material.

25. An integrated circuit apparatus for facilitating the interconnection of one or more circuitry manufacture, comprising:
means for defining a top carrier substrate surface and a bottom carrier substrate surface and for receiving one or more circuitry manufacture on the top carrier substrate surface and the bottom carrier substrate surface;
means for defining vias from the top carrier substrate surface to the bottom carrier substrate surface and for defining interior via surfaces for receiving one or more circuitry manufacture; and
means for defining cavity surfaces on the top and/or bottom carrier substrate surfaces and for receiving one or more circuitry manufacture on the interior cavity surfaces.

26. The integrated circuit apparatus of claim 25, further comprising means for creating an electrically conductive connection through the means for defining vias on the interior via surfaces.

27. An integrated circuit, comprising:
a carrier substrate defining a top surface and a bottom surface, the carrier substrate configured to receive one or more circuitry manufacture on the top surface and the bottom surface;
one or more carrier substrate vias penetrating the carrier substrate so that the carrier substrate vias define vias from the top surface to the bottom surface of the carrier substrate and further define interior via surfaces, the one or more carrier substrate vias configured to receive one or more circuitry manufacture on the interior via surfaces;
one or more carrier substrate cavities, the one or more carrier substrate cavities formed on the top and/or bottom surfaces of the carrier substrate, the one or more carrier substrate cavities defining interior cavity surfaces and configured to receive one or more circuitry manufacture on the interior cavity surfaces;
a first circuit device mounted to the carrier substrate and further mounted relative to a carrier substrate cavity by one or more circuitry manufacture; and
a second circuit device mounted to the carrier substrate by one or more circuitry manufacture and in electrical communication with the first circuit device.

28. The integrated circuit of claim 27, wherein the first circuit device comprises a Micro Electro Mechanical System (MEMS) device.

29. The integrated circuit of claim 28, wherein the MEMS device is mounted relative to the carrier substrate cavity by one or more circuitry manufacture by mounting the MEMS device in the carrier substrate cavity.

30. The integrated circuit of claim 28, wherein the MEMS device is mounted relative to the carrier substrate cavity by one or more circuitry manufacture by mounting the MEMS device atop the carrier substrate cavity.

31. The integrated circuit of claim 28, wherein the second circuit device is in electrical communication with the MEMS device through one or more carrier substrate vias and circuitry manufacture deposited in the carrier substrate vias.

32. The integrated circuit of claim 28, wherein the one or more circuitry manufacture mounting the first and second circuit devices to the carrier substrate comprises a thin film interconnect.
